(19) United States
(12) Patent Application Publication
(10) Pub. No.: US 2026/0021515 A1
(43) Pub. Date: Jan. 22, 2026

(54) MAINTENANCE DEVICE FOR TESTING EQUIPMENT AND METHOD OF USING THE SAME

(71) Applicant: SILICONWARE PRECISION INDUSTRIES CO., LTD., Taichung City (TW)

(72) Inventor: Cheng-Shao CHEN, Taichung City (TW)

(21) Appl. No.: 18/904,314

(22) Filed: Oct. 2, 2024

(30) Foreign Application Priority Data
Jul. 19, 2024 (TW) 113127204

(51) Int. Cl. B08B 7/00; G01R 1/073

(52) U.S. Cl. CPC B08B 7/0014; G01R 1/07342

(57) ABSTRACT

A maintenance device for a testing equipment is provided, which includes: a cleaning assembly including a cleaning plate and a cleaning material; and a replacement assembly including a flattening roller and a removal roller. The cleaning material is applied onto an upper surface of the cleaning plate by rolling and compressing via the flattening roller, and the cleaning material is removed from the cleaning plate by the removal roller after the completion of the cleaning. The flattening roller is utilized to flatly apply the cleaning material to the cleaning plate, so as to avoid damage to the probe card of the testing equipment due to unevenness of the cleaning material, and the removal roller is used to automatically and quickly remove the used cleaning material to speed up the execution of maintenance work and improve the work efficiency of the maintenance device.

### CROSS-REFERENCE TO RELATED APPLICATIONS

The present application is based upon and claims the right of priority to TW Patent Application No. 113127204, filed July 19, 2024, the disclosure of which is hereby incorporated by reference herein in its entirety for all purposes.

### BACKGROUND

### 1. Technical Field

The present disclosure relates to a maintenance device, and more particularly, to a maintenance device and an application method thereof for a semiconductor testing equipment.

### 2. Description of Related Art

With the booming development of portable electronic products in recent years, the development of various related products is also moving towards the trend of high density, high performance, lightness, thinness, shortness and smallness. For this reason, the semiconductor industry has also developed various packaging aspects that integrate multiple functions in order to meet the requirements of thin, light, short, small and high-density electronic products. Under the influence of this trend, the widths of circuits on semiconductor components and substrates used to carry the semiconductor components are also increasingly reduced, such that more circuits and components can be accommodated on the same area of semiconductor components and substrates. To this end, the industry has also developed various testing equipment to test these semiconductor components and/or substrates, and probe cards are especially important since they are often used in the semiconductor manufacturing process to test various circuits on the wafer surface.

However, during the testing process, some foreign matter such as residues will adhere to the probe card; therefore, the probe card must be cleaned and maintained using cleaning materials such as probe cleaning paper to remove the stuck foreign matter. However, in the conventional cleaning and maintenance methods, the probe cleaning paper needs to be manually replaced, and the manual replacement operation of the probe cleaning paper is not only slow but also prone to form bubbles when the probe cleaning paper is pasted, thereby making the probe cleaning paper uneven and affecting the cleaning effect (the probe card may even be damaged in serious cases).

Therefore, how to overcome the aforementioned problems of the prior art has become an urgent issue to be solved.

### SUMMARY

In view of the aforementioned shortcomings of the prior art, the present disclosure provides a maintenance device for a testing equipment comprising a probe card, the maintenance device comprises: a cleaning assembly comprising a cleaning plate and a cleaning material for cleaning the probe card; and a replacement assembly comprising a flattening roller and a removal roller, wherein the cleaning material is applied onto a surface of the cleaning plate by rolling and compressing via the flattening roller, the cleaning assembly cleans a surface of the probe card by contacting the cleaning material with the surface of the probe card, and the cleaning material is removed from the cleaning plate by the removal roller after the completion of the cleaning.

The present disclosure further provides an application method of a maintenance device for testing equipment, the testing equipment comprises a probe card, the application method comprises: providing a cleaning assembly comprising a cleaning plate and a cleaning material, wherein the cleaning material is applied onto a surface of the cleaning plate, and the cleaning material is applied onto the cleaning plate by rolling and compressing via a flattening roller of a replacement assembly; cleaning the testing equipment, wherein the cleaning material of the cleaning assembly contacts and cleans a surface of the probe card; and removing the cleaning material, wherein the cleaning material is removed from the cleaning plate of the cleaning assembly via a removal roller of the replacement assembly after the surface of the probe card is cleaned.

In the aforementioned maintenance device and application method thereof for testing equipment, the replacement assembly further comprises a take-and-release structure for taking and releasing the cleaning material.

In the aforementioned maintenance device and application method thereof for testing equipment, a surface of the removal roller is provided with a plurality of protrusions for removing the cleaning material.

In the aforementioned maintenance device and application method thereof for testing equipment, the cleaning plate is applied with the cleaning material after the cleaning material that has been used for cleaning is removed.

In the aforementioned maintenance device and application method thereof for testing equipment, the cleaning assembly moves vertically to make the cleaning plate drive the cleaning material from bottom to top to contact a bottom side of the probe card for cleaning.

As can be seen from the above, the present disclosure utilizes the flattening roller to flatly apply the cleaning material to the cleaning plate, so as to avoid damage to the probe card of the testing equipment due to unevenness of the cleaning material, and uses the removal roller to automatically and quickly remove the used cleaning material to speed up the execution of maintenance work and improve the work efficiency of the maintenance device.

### BRIEF DESCRIPTION OF THE DRAWINGS

FIG. 1A to FIG. 1E are schematic partial side views illustrating a maintenance device and an application method thereof for a testing equipment according to an embodiment of the present disclosure.

FIG. 2 is a flowchart illustrating an application method according to an embodiment of the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “up,” “upper,” “top,” “down,” “lower,” “bottom,” “a,” “one,” “first,” “second,” and the like are merely for clear explanation rather than limiting the practicable scope of the present disclosure, and thus, alterations or adjustments of the relative relationships thereof without essentially altering the technical contents should still be considered in the practicable scope of the present disclosure.

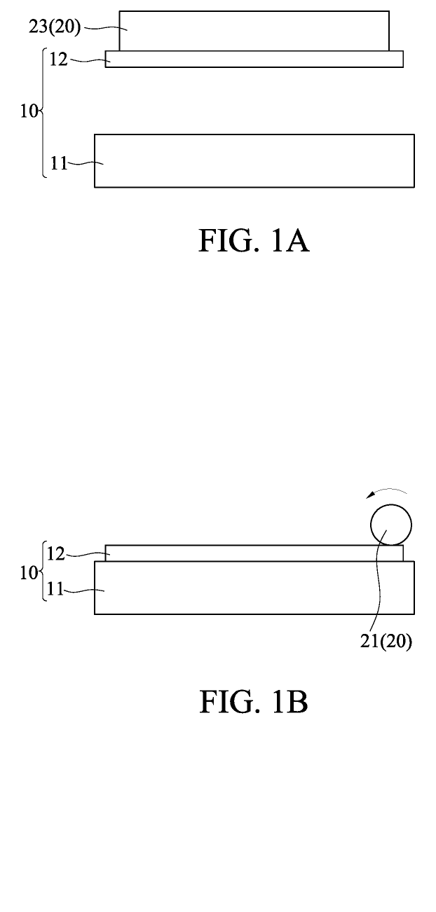

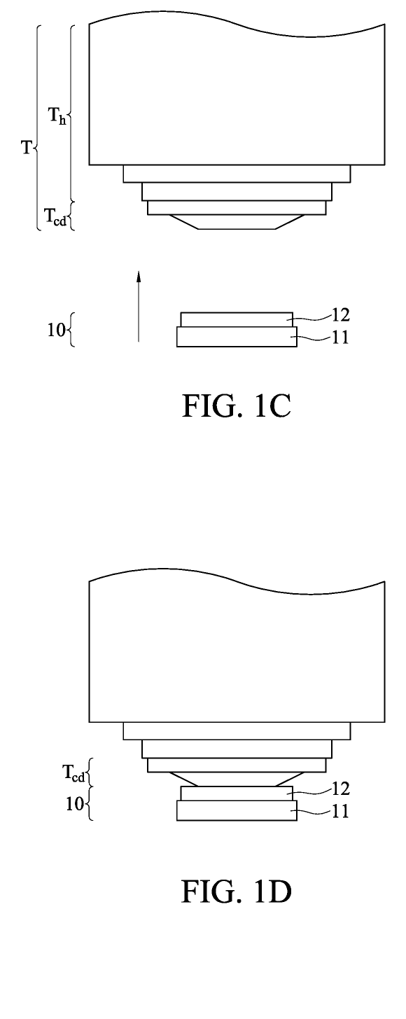

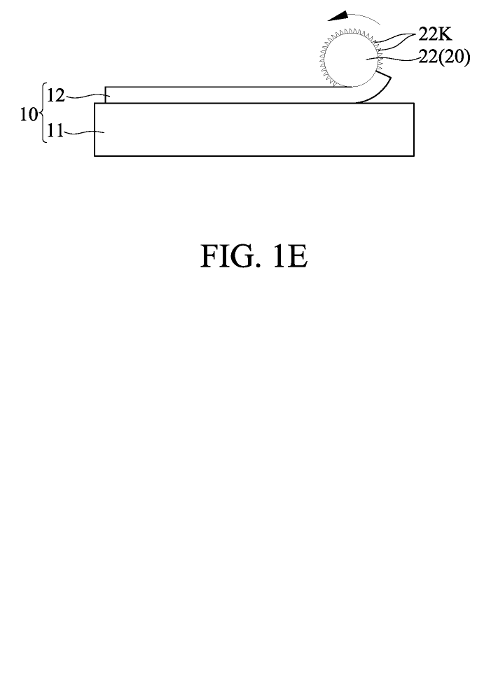

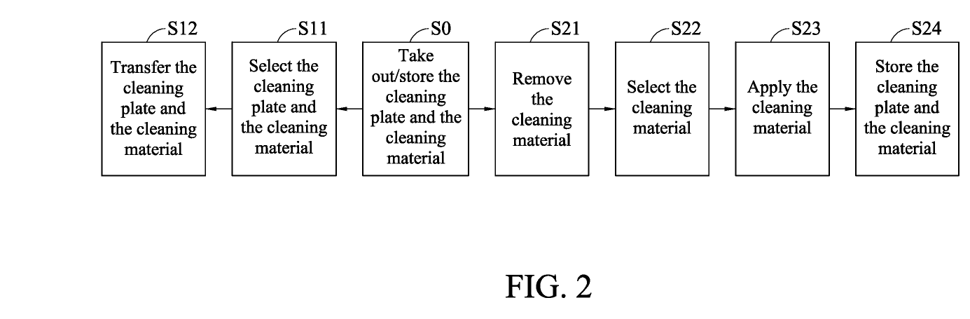

FIG. 1A to FIG. 1E are schematic partial side views illustrating a maintenance device and an application method thereof for a testing equipment according to an embodiment of the present disclosure; and FIG. 2 is a flowchart illustrating an application method according to an embodiment of the present disclosure.

As shown in FIG. 1A, in an embodiment, an application method of a maintenance device for a testing equipment includes: providing a cleaning assembly 10, wherein the cleaning assembly 10 includes a cleaning material 12 and a cleaning plate 11. The cleaning material 12 is, for example, probe cleaning paper or probe cleaning film used to clean a probe card T_{cd} (see FIG. 1C and FIG. 1D). The testing equipment T (see FIG. 1C and FIG. 1D) must use the probe card T_{cd} that corresponds to the object under test (not shown, such as a wafer with a specific circuit structure formed on the surface thereof), that is, different probe cards T_{cd} correspond to different objects under test; therefore, the cleaning material 12 must also be of a form or model that corresponds to the probe card T_{cd} to be cleaned, so as to avoid damage to the probe card T_{cd} due to the mismatch between the surface of the cleaning material 12 and the surface of the probe card T_{cd}.

Then, the cleaning material 12 is applied onto the cleaning plate 11 by a replacement assembly 20. The replacement assembly 20 can include a take-and-release structure 23 for taking and releasing the cleaning material 12, and the take-and-release structure 23 is such as a Bernoulli vacuum pad that uses air suction to generate vacuum suction to suck and fix the cleaning material 12. The cleaning plate 11 can be, for example, a wide area polish plate (WAPP). The cleaning plate 11 is used to carry and fix the cleaning material 12 and to drive the cleaning material 12 to move so that the cleaning material 12 contacts and cleans the surface of the probe card T_{cd}, and then the cleaning plate 11 drives the cleaning material 12 to move away from the probe card T_{cd} after the cleaning is completed.

As shown in FIG. 1B, when the cleaning material 12 is applied onto the upper surface of the cleaning plate 11, a flattening roller 21 of the replacement assembly 20 rolls on the surface of the cleaning material 12 to apply the cleaning material 12 so as to prevent bubbles from existing between the cleaning material 12 and the cleaning plate 11, such that the cleaning material 12 can be flatly applied onto the surface of the cleaning plate 11.

Please refer to FIG. 1C and FIG. 1D, and then the testing equipment T is cleaned to mainly clean the probe card T_{cd} therein. The testing equipment T includes a probe head Tₕ for fixing the probe card T_{cd}. The cleaning plate 11 of the cleaning assembly 10 drives the cleaning material 12 to move so that the cleaning material 12 contacts the surface of the probe card T_{cd}, so as to move foreign matter (not shown, such as the wafer residue and the like adhered during the previous test) from the surface of the probe card T_{cd} to the surface of the cleaning material 12, thereby cleaning the probe card T_{cd}. After the cleaning is completed, the cleaning plate 11 of the cleaning assembly 10 drives the cleaning material 12 to move away from the probe card T_{cd}. In an embodiment, the cleaning assembly 10 can move vertically, so that the cleaning plate 11 of the cleaning assembly 10 drives the cleaning material 12 to move from bottom to top so as to contact the bottom side of the probe card T_{cd}; and after the cleaning is completed, the cleaning plate 11 drives the cleaning material 12 to move from top to bottom so as to move away from the bottom side of the probe card T_{cd}.

As shown in FIG. 1E, the cleaning material 12 is finally removed. After the cleaning procedure of the surface of the probe card T_{cd} is completed, a removal roller 22 of the replacement assembly 20 is moved to the surface of the cleaning material 12 of the cleaning assembly 10 and is adjacent to one side edge of the cleaning material 12. The surface of the removal roller 22 can be provided with a plurality of protrusions 22k (e.g., spikes) for removing the cleaning material 12. The protrusions 22k on the surface of the removal roller 22 can penetrate into the cleaning material 12 so that the cleaning material 12 can adhere to the surface of the removal roller 22 from the edge of the cleaning material 12. Then, the removal roller 22 is rolled along the surface of the cleaning material 12 toward the other side edge of the cleaning material 12 so as to roll up the cleaning material 12 and wrap the cleaning material 12 on the surface of the removal roller 22, thereby removing the cleaning material 12 from the cleaning plate 11.

After the used cleaning material 12 is removed from the cleaning plate 11, the above steps can be repeated to apply a new and unused cleaning material 12 to the cleaning plate 11, so that the next cleaning operation can be performed to the probe card T_{cd} of the testing equipment T.

The process described above is the fundamental operation for using the maintenance device. The maintenance device provided in the embodiment can further control the work thereof according to the process shown in FIG. 2 for example. For instance, step S0, step S11 and step S12 are performed before the maintenance work is performed. In step S0: take out/store a cleaning plate and a cleaning material. In step S11: select the cleaning plate and the cleaning material via manual selection or automatic selection by an automated equipment (e.g., select the cleaning material that corresponds to the probe card to be cleaned and maintained and select the cleaning plate applied with the cleaning material). In step S12, transfer the cleaning plate and the cleaning material (e.g., transfer the selected cleaning plate and the selected cleaning material to the testing equipment to be maintained so as to maintain the testing equipment). Step S0, step S21, step S22, step S23 and step S24 are performed after the cleaning plate and the cleaning material of the cleaning assembly are used. In step S0: take out/store the cleaning plate and the cleaning material. In step S21: remove the cleaning material (e.g., remove the old and used cleaning material that is stained with foreign matter or residue from the cleaning plate). In step S22: select a cleaning material (e.g., select the form or model of a new cleaning material to be applied). Step S22 can also be carried out according to the manually inputted data, or step S22 can be carried out automatically by the automated equipment according to preset procedures and options, and the present disclosure is not limited to as such. In step S23: apply the cleaning material (e.g., apply the selected cleaning material to the surface of the cleaning plate). In step S24: store the cleaning plate and the cleaning material (e.g., store the cleaning plate applied with the cleaning material together for the next maintenance work). The specific methods used to perform the relevant steps in this process example are as mentioned above, so the specific methods will not be repeated here.

The embodiment further provides a maintenance device for testing equipment T, the testing equipment T includes a probe card T_{cd}, and the maintenance device includes: a cleaning assembly 10 including a cleaning plate 11 and a cleaning material 12 for cleaning the probe card T_{cd}; and a replacement assembly 20 including a flattening roller 21 and a removal roller 22, wherein the cleaning material 12 is applied onto an upper surface of the cleaning plate 11 by rolling and compressing via the flattening roller 21, and the cleaning assembly 10 cleans a surface of the probe card T_{cd} by contacting the cleaning material 12 with the surface of the probe card T_{cd}, and the cleaning material 12 is removed from the cleaning plate 11 by the removal roller 22 after the completion of the cleaning.

In preferred embodiments, the replacement assembly 20 further comprises a take-and-release structure 23 for taking and releasing the cleaning material 12.

In preferred embodiments, a surface of the removal roller 22 is provided with a plurality of protrusions 22k for removing the cleaning material 12.

In preferred embodiments, the cleaning plate 11 is applied with the cleaning material 12 after the cleaning material 12 that has been used for cleaning is removed.

In preferred embodiments, the cleaning assembly 10 moves vertically to make the cleaning plate 11 drive the cleaning material 12 from bottom to top to contact a bottom side of the probe card T_{cd} for cleaning.

To sum up, the present disclosure utilizes the flattening roller to flatly apply the cleaning material to the cleaning plate, so as to avoid damage to the probe card of the testing equipment due to unevenness of the cleaning material, and uses the removal roller to automatically and quickly remove the used cleaning material to speed up the execution of maintenance work and improve the work efficiency of the maintenance device.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A maintenance device for a testing equipment comprising a probe card, the maintenance device comprising:
a cleaning assembly comprising a cleaning plate and a cleaning material for cleaning the probe card; and
a replacement assembly comprising a flattening roller and a removal roller,
wherein the cleaning material is applied onto a surface of the cleaning plate by rolling and compressing via the flattening roller, the cleaning assembly cleans a surface of the probe card by contacting the cleaning material with the surface of the probe card, and the cleaning material is removed from the cleaning plate by the removal roller after the completion of the cleaning.

2. The maintenance device of claim 1, wherein the replacement assembly further comprises a take-and-release structure for taking and releasing the cleaning material.

3. The maintenance device of claim 1, wherein a surface of the removal roller is provided with a plurality of protrusions for removing the cleaning material.

4. The maintenance device of claim 1, wherein the cleaning plate is applied with the cleaning material after the cleaning material that has been used for cleaning is removed.

5. The maintenance device of claim 1, wherein the cleaning assembly moves vertically to make the cleaning plate drive the cleaning material from bottom to top to contact a bottom side of the probe card for cleaning.

6. An application method of a maintenance device for testing equipment, the testing equipment comprising a probe card, the application method comprising:
providing a cleaning assembly comprising a cleaning plate and a cleaning material, wherein the cleaning material is applied onto a surface of the cleaning plate, and the cleaning material is applied onto the cleaning plate by rolling and compressing via a flattening roller of a replacement assembly;
cleaning the testing equipment, wherein the cleaning material of the cleaning assembly contacts and cleans a surface of the probe card; and
removing the cleaning material, wherein the cleaning material is removed from the cleaning plate of the cleaning assembly via a removal roller of the replacement assembly after the surface of the probe card is cleaned.

7. The application method of claim 6, wherein the replacement assembly further comprises a take-and-release structure for taking and releasing the cleaning material.

8. The application method of claim 6, wherein a surface of the removal roller is provided with a plurality of protrusions for removing the cleaning material.

9. The application method of claim 6, wherein the cleaning plate is applied with the cleaning material after the cleaning material that has been used for cleaning is removed.

10. The application method of claim 6, wherein the cleaning assembly moves vertically to make the cleaning plate drive the cleaning material from bottom to top to contact a bottom side of the probe card for cleaning.
